(19) United States
(12) Patent Application Publication
(10) Pub. No.: US 2011/0306180 A1
(43) Pub. Date: Dec. 15, 2011

(54) Systems, Methods and Products Involving Aspects of Laser Irradiation, Cleaving, and/or Bonding Silicon-Containing Material to Substrates

(76) Inventor: Venkatraman Prabhakar, Pleasanton, CA (US)

(21) Appl. No.: 13/160,476

(22) Filed: Jun. 14, 2011

Related U.S. Application Data
(60) Provisional application No. 61/354,682, filed on Jun. 14, 2010.

(51) Int. Cl. H01L 21/301; H01L 21/265; H01L 21/268; H01L 21/30

(52) U.S. Cl. 438/458; 438/455; 257/E21.211; 257/E21.334; 257/E21.347

(57) ABSTRACT

Systems, methods and products by process are disclosed relating to structures and/or fabrication thereof as relating, for example, to optical/electronic applications such as solar cells and displays. In one exemplary implementation, there is provided a method of producing a composite structure. Moreover, the method may include engaging a silicon-containing material into contact with a surface of the substrate and irradiating/treating the silicon-containing piece with a laser.

### CROSS-REFERENCE TO RELATED APPLICATION(S)

This application claims benefit and priority of U.S. provisional patent application No. 61/354,682, filed Jun. 14, 2010, which is incorporated herein by reference in entirety.

### BACKGROUND

1. Field

Aspects associated with the present innovations relate to structures and/or fabrication thereof, and, more particularly, to methods and products consistent with composite structures, e.g. for optical/electronic applications such as solar cells and displays, which may include a silicon-containing material bonded to a substrate.

2. Description of Related Information

Existing literature discusses producing thin layers of semiconductor material by implanting ions into the base material up to a specified junction, followed by thermal treatment and application of force to separate the thin layer along the junction. Such methods typically involve implantation of light ions such as H and He into silicon at the desired depth. After that, a thermal treatment is performed to stabilize the microcavities. In existing systems, this thermal treatment step is performed at equal to or greater than 550° C., a temperature too high to reliably perform on glass substrates. For many applications, such as solar, use of cheaper glass such as borosilicate/borofloat and soda-lime glass is essential. Therefore, use of glass substrates that withstand higher temperatures such as the Corning “Eagle” glass is not practical. While some lower temperature thermal treatments exist, they are unable to reliably separate thin layers on glass. The conventional treatments also require an atomically smooth glass with an RMS roughness of <5 A. Although smooth glasses such as display industry glasses similar to the Corning “Eagle” are available, the cheaper glasses such as borofloat and soda-lime glass have a much rougher surface. If conventional techniques were attempted on cheaper glass, delamination would occur at another weak interface, such as the interface between the nitride and the silicon layer, instead of at the damaged microcavities. Other existing methods include laser treatment techniques, e.g., often used to separate thin LiNbO3 layers on silicon substrates. However, such techniques require very high power CO2 laser, which is not suitable for a silicon layer. In addition, these techniques are used to bond silicon on insulator (either oxide or nitride). In some instances, such as certain applications of solar cells and flat panel displays, it is necessary to bond silicon-based materials or layers to another silicon-based layer (e.g., an amorphous or polycrystalline silicon layer, etc). Some existing techniques, for example, rely on a thin oxide layer between two silicon layers to bond silicon to silicon. However, such thin oxide layers may be undesirable, can interfere with further processing steps, and/or present other drawbacks related to the silicon-based bonding interfaces.

As set forth below, one or more exemplary aspects of the present inventions may overcome these or other drawbacks and/or otherwise impart innovative aspects.

### SUMMARY

Systems, methods, devices, and products of processes consistent with the innovations herein relate to composite structures composed of a silicon-containing material bonded to a substrate.

It is to be understood that both the foregoing general description and the following detailed description are exemplary and explanatory only and are not restrictive of the invention, as described. Further features and/or variations may be provided in addition to those set forth herein. For example, the present invention may be directed to various combinations and subcombinations of the disclosed features and/or combinations and subcombinations of several further features disclosed below in the detailed description.

### DESCRIPTION OF THE DRAWINGS

The accompanying drawings, which constitute a part of this specification, illustrate various implementations and aspects of the present invention and, together with the description, explain the principles of the invention. In the drawings:

FIG. 1 illustrates an exemplary structure including a silicon-containing piece and a substrate with a plurality of layers/coatings, showing laser irradiation from the bottom, consistent with aspects related to the innovations herein.

FIG. 2 illustrates a representative structure showing an exemplary cleaving operation, consistent with one or more aspects related to the innovations herein.

FIG. 3 illustrates an exemplary structure including a silicon-containing piece and a substrate with a plurality of layers/coatings, showing laser irradiation from the top, consistent with aspects related to the innovations herein.

FIGS. 4A, 4B and 4C illustrate an exemplary method of producing a structure, including implantation, various alternate/optional anneal steps, and laser treatment, consistent with aspects related to the innovations herein.

FIGS. 5A, 5B and 5C illustrate another exemplary method of producing a structure, including implantation, various alternate/optional anneal steps, and laser treatment, consistent with aspects related to the innovations herein.

FIGS. 6A, 6B, 6C and 6D illustrate still another exemplary method of producing a structure, including implantation, various alternate/optional anneal steps, and laser treatment, consistent with aspects related to the innovations herein.

FIGS. 7A, 7B and 7C illustrate yet another exemplary method of producing a structure, including implantation, various alternate/optional anneal steps, and laser treatment, consistent with aspects related to the innovations herein.

FIGS. 8A, 8B and 8C illustrate still a further exemplary method of producing a structure, including implantation, various alternate/optional anneal steps, and laser treatment, consistent with aspects related to the innovations herein.

FIGS. 9A-9B illustrates exemplary aspects of laser treatment in producing a structure, consistent with aspects related to the innovations herein.

FIGS. 10A-10B illustrate further exemplary aspects regarding laser treatment, consistent with aspects related to the innovations herein.

FIGS. 11A-11B illustrate still further exemplary aspects regarding laser treatment, consistent with aspects related to the innovations herein.

FIG. 12 illustrates aspects of an illustrative process applicable to flat panel displays and/or thin film transistors, consistent with aspects of the innovations herein.

### DETAILED DESCRIPTION OF EXEMPLARY IMPLEMENTATIONS

Reference will now be made in detail to the invention, examples of which are illustrated in the accompanying drawings. The implementations set forth in the following description do not represent all implementations consistent with the claimed invention. Instead, they are merely some examples consistent with certain aspects related to the invention. Wherever possible, the same reference numbers will be used throughout the drawings to refer to the same or like parts.

Systems and methods consistent with aspects of the inventions herein including laser irradiation, bonding, anneal and/or cleaving of silicon-containing material in relation to a substrate are disclosed. In one exemplary implementation, there is provided a method of producing a composite structure composed of a silicon-containing material bonded to a substrate. Moreover the method may include implanting ions into silicon-containing material to a depth, providing a SiN/SiO2/Si-containing layer/coating on the substrate, engaging the silicon-containing piece into contact with the substrate, and irradiating/treating the silicon-containing piece with a laser having a wavelength of between about 350 nm to about 1070 nm. Additionally, according to certain aspects of innovations herein, thermal treatments at temperatures at or below 500° C. may be performed, to enable use with standard glass materials. Further, aspects of the innovations herein may utilize sufficient temperatures during the anneal process, such that duration of the anneal is short enough that cost of manufacture is not unacceptably increased.

Systems, methods, devices, and products of processes consistent with the innovations herein relate to composite structures composed of a silicon-containing material bonded to a substrate as well as methods of manufacturing same. As set forth in more detail elsewhere, some exemplary implementations herein include irradiating/treating a silicon-containing piece with a laser having a wavelength of between about 350 nm to about 1070 nm. Here, for example, the irradiation step may be performed with a laser having a wavelength between about 500 nm and about 600 nm, of about 515 nm, of about 532 nm, or in other ranges set forth herein. Moreover, as set forth in more detail below and in accordance with the disclosure, aspects of the innovations herein may optionally include one or more of the following and/or other variations and laser treatment as follows: (1) use of laser scanned across a silicon-containing material bonded to a substrate, such as a glass substrate having a plurality of SiN/SiO2/Si coatings/layers, to help the cleaving of silicon on glass to desired thickness; (2) use of laser anneal to strengthen the bond between the silicon and the substrate; (3) use of laser anneal to weaken the damaged layer created by the light ion implantation; and/or (4) application of one or more lasers either through the substrate, or through the silicon material, or both.

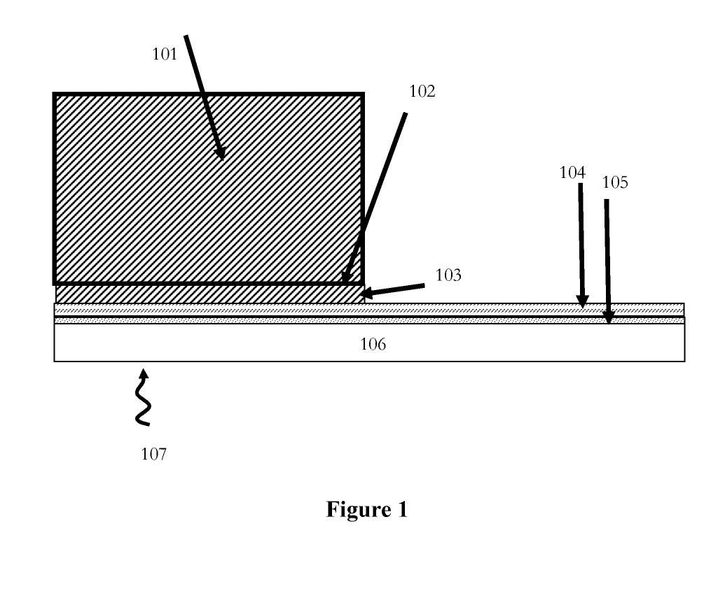

FIG. 1 is a cross-section of an illustrative implementation consistent with one or more aspects of the innovations herein. As shown by way of illustration in FIG. 1, a substrate 106, such as glass, may have a first layer/coating referenced here as layer 105. The substrate may also have a second layer/coating 104. Here, for example, the first layer and the second layer may be layers/coatings that comprise SiN, SiO2 and/or Si, also referred to herein as SiN/SiO2/Si-containing layers/coatings. In one representative implementation, these layers/coatings may include a first layer/coating comprising SiN and a second layer/coating comprising amorphous silicon or poly silicon. In other implementations, layer 104 may be included with or without layer 105. The amorphous or poly silicon layer 104 may be directly on the glass substrate or may be on top of one or more other layers deposited or coated on the glass, such as SiO₂ (silicon dioxide) or SiN (silicon nitride), SiON, amorphous silicon or poly silicon, ITO (Indium Tin oxide), SiGe (silicon germanium) and other silicon-based based materials such as SiC (silicon with a small percentage of carbon), SiGeC, silicon-germanium-carbon with both Ge and C mixed in the silicon, and other such silicon derivative materials applicable to the use desired.

Additionally, a silicon-containing material 101, such as a silicon wafer or piece, may be bonded on the substrate 104. Such silicon material 101 may have a portion 103 which has been implanted with a light ion, e.g. H or He, or a combination of light ions before the bonding. Alternately, the light ions may also be implanted at other times (before cleaving), such as after bonding. The depth at which the ions are implanted is shown as a damaged region 102 in FIG. 1.

As shown in FIG. 1, a laser 106 which can be absorbed by the silicon is scanned across the area of the silicon-containing material 103 and/or the substrate 106/layers 104, 105. Here, for example, the laser may be applied consistent with innovations herein to create thermal mismatch or stress at the damaged region 102. Further, the laser wavelength in some implementations may be chosen so that the substrate 106 is transparent to the laser. In some exemplary implementations, the wavelength of the laser can be in the range of about 350 nm to about 1070 nm, or about 350 nm to about 850 nm, in narrower ranges, such as about 500 nm to about 600 nm, and/or at specific wavelengths. For example, in some implementations, laser irradiation may be applied at a wavelength of 515 nm or of 532 nm. In one exemplary implementation, the layer 105 may be a silicon nitride (SiN) layer deposited by PECVD (plasma enhanced chemical vapor deposition). Further, some implementations may include SiN layers having a refractive index of about 1.7 to about 2.2. In one exemplary implementation, this SiN layer may have a refractive index of about 2.0, and therefore it acts as an anti-reflective coating in between the silicon and glass layers. In some implementations, the SiN layer could be modified with oxygen to form SiON (silicon oxynitride) and/or there could be a thin layer (e.g., about 5 to about 30 nm; and, in some exemplary implementations, about 10 nm) of SiON or SiO2 deposited on top of the SiN layer to achieve better passivation and stress relief.

In still further embodiments, additional layers may be deposited on top of the SiN/SiO₂/Si layers before the bonding step, as needed, e.g., for specific applications, etc. For example, a silicon layer may be deposited over the lower SiN, SiO₂, Si, etc. layer in certain instances. In exemplary implementations layer 104 may be a layer of amorphous and poly silicon. The deposition conditions of the amorphous silicon may be varied to achieve low stress levels of about −100 MPa (compressive) to +100 MPa (tensile).

In some exemplary implementations, the glass can be any variety of glass that is transparent to the chosen wavelength ranging in size from about 150 mm×150 mm to a Gen 10 glass that is about 3 m×3 m. In one exemplary implementation, the glass may be a Gen 5 glass (1.1 m×1.3 m). As to the type of glass used, the innovations herein are particularly well suited to solar cell fabrication using soda-lime glass or borosilicate/borofloat glass. Different types of glasses could be chosen depending on the application. In some implementations, the glass could be a soda-lime or float glass with or without heat strengthening or tempering. In other implementations, borosilicate or aluminosilicate glasses such as the Schott Borofloat or the Corning Eagle could be used.

In accordance with the above and/or additional aspects of laser irradiation, anneal or other features set forth elsewhere herein, innovative systems, methods and products by processes may be achieved. According to some aspects of the innovations herein, only thermal treatments at temperatures at or below 500° C. are needed performed, enabling use of standard glass materials. Here, for example, the present innovations may comprise a step of annealing at a temperature between about 200° C. to about 500° C., between about 200° C. to about 450° C., between about 250° C. to about 350°, or at about 300° C. Moreover, the present innovations may comprise a step of annealing at a temperature between about 200° C. to about 500° C., between about 200° C. to about 450° C., between about 250° C. to about 350°, or at about 300° C. to achieved the desired anneal within a period of less than about 45 minutes. Furthermore, various implementations of the innovations herein may utilize sufficient temperatures during the anneal process, such that duration of the anneal is short enough that cost of manufacture is not unacceptably increased.

Innovations herein also overcome technical problems associated with lower temperature anneal, including insufficient bond strength that leads to cleaving at the nitride interface (i.e. between layers 103 and 104, FIG. 1), rather than at the damaged layer 102. Aspects of systems and methods consistent with the innovations herein may involve laser treatment with or without a low temperature (<500° C.) thermal treatment. In some exemplary implementations, the laser treatment may strengthen the semiconductor material bonding to the substrate, such as glass, and may weaken the damaged layer created by the implantation. As such, cleaving of the semiconductor material may be provided. Further, some implementations of the innovations herein do not involve anneals with temperature greater than 500° C. and are therefore compatible with low temperature substrates such as glass and plastic. Moreover, laser treatments consistent with the innovations herein may be a few minutes long, compared to the high temperature anneal which takes hours to complete.

In certain embodiments, this layer may also be silicon-germanium (SiGe). In one exemplary implementation, layer 104 is amorphous silicon deposited by PECVD. Further, a crystalline (single crystal or multi-crystal) silicon piece 101 is bonded on the substrate. In one exemplary implementation, the silicon piece 101 is mechanically held in close contact with layer 104 while the laser 7 is scanned over the area to be bonded/cleaved. The silicon piece 101 may have a region 3, which has been implanted with a light ion e.g. H or He or a combination of light ions, before bonding. The mean depth at which the ions are implanted is shown as region 102 in FIG. 1. In exemplary implementations, this region 102 is damaged by the ion implantation. Laser 107, which is at a wavelength that is well absorbed by silicon, is scanned across the area of silicon 103. This laser wavelength is chosen to be well absorbed by both amorphous silicon and crystalline silicon. The laser can create stress due to thermal mismatch as well as hydrogen induced vacancies also known as bubbles or microcavities in region 102. The laser wavelength is chosen in some implementations so that the glass 106 is transparent to the laser. In some exemplary implementations, the laser wavelength can be in the range of about 350 nm to about 1070 nm or 350 nm to about 850 nm, or in other ranges or at other wavelengths set forth herein. In one exemplary implementation, the laser wavelength is 532 nm. In another exemplary implementation, the laser wavelength is 515 nm. The spot size of the laser could be between about 5 μm and about 100 μm, for example. The laser line can also be a line source with the long axis being about 1 mm to about 500 mm and the short axis size being between about 5 μm and about 100 μm, for example. In one exemplary implementation, the laser is a line source of approximately 20 mm×20 μm. The laser beam is rastered or otherwise distributed/diffused to cover the area of the silicon piece that is desired to be cleaved/bonded.

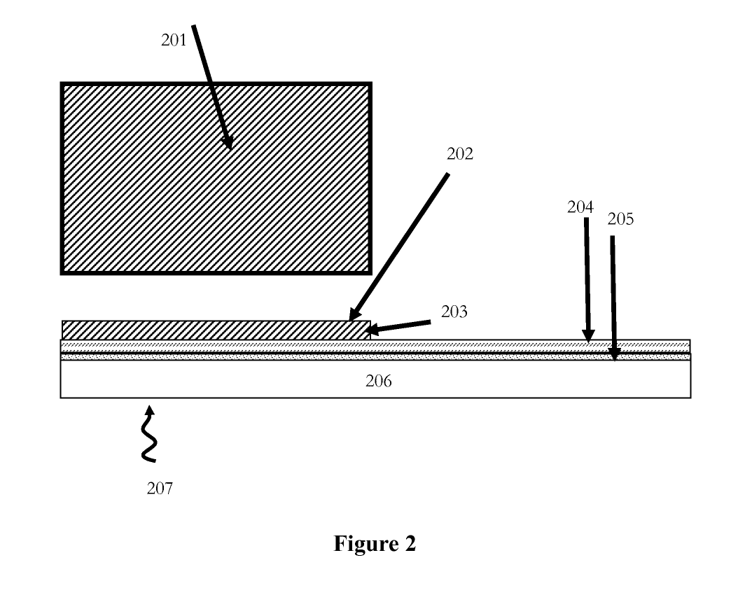

FIG. 2 illustrates an exemplary structure showing a cleaving aspect, consistent with one or more aspects related to the innovations herein. The system of FIG. 2 is similar to that of FIG. 1, including the substrate 206, layer 205, and the amorphous or poly-silicon containing layer 204, silicon-containing material 201, 203, and laser 207. The implementation illustrated in FIG. 2 further shows the silicon-containing material cleaved into two portions, a first portion 201 that is removed, and a second portion 203 that remains on the substrate.

In some implementations, the cleaving step and the laser step may be performed either sequentially or together in the same step. In one exemplary implementation, the cleaving is done immediately at the end of the laser anneal, by using mechanical force to separate the region 203 which remains bonded on the layer 204 from the rest of the silicon wafer 201. When these steps are performed together, the mechanical force necessary to cleave the wafer may be applied at the same time that the laser anneal is provided. In alternative implementations of the innovation herein, further low temperature anneals may be performed before or after the laser anneal to assist with the cleaving process. In some implementations, the anneal can be between about 200 C to about 500 C, e.g., for about 5 min to about 30 min. In one exemplary implementation, an anneal is done at 300 C for 15 minutes prior to the laser treatment. In another exemplary implementation an anneal may be done in 2 steps, one after deposition of layer 204 and another after the laser anneal.

As used herein, SiN/SiO2/Si-containing coating/layer is defined as a layer containing one or more layers of silicon nitride (with varying percentage of Nitrogen) or silicon oxide or silicon oxynitride (which includes both O and N incorporated). Further, such layer may also comprise amorphous silicon or poly silicon material, and such layer may also be formed on top of a first SiN/SiO2/Si layer. Here, for example, layers/coatings comprising SiN may be provided in thickness ranges of between about 1 nm and about 100 nm, between about 50 nm and about 80 nm, or of about 75 nm. Additionally, layers/coatings comprising Si (amorphous silicon or poly silicon) may be provided in thickness ranges of between about 1 nm and about 100 nm, between about 20 nm and about 75 nm, or between about 45 nm and about 50 nm. Further, layers/coatings comprising SiO2 may be provided in thicknesses of between about 1 nm and about 50 nm, between about 5 nm and about 20 nm, or of about 10 nm. In one illustrative implementation, for example, the SiN/SiO2/Si-containing layers could be about 70-80 nm or about 75 nm of SiN deposited by PECVD using SiH4 (silane) and NH3 (ammonia) gases followed by about 40-50 nm or about 45 nm of amorphous silicon also deposited by PECVD using SiH4. An alternative embodiment could be about 48-58 nm or about 53 nm of SiN followed by about 5-15 nm or about 10 nm of SiO2 followed by about 40-50 nm or about 45 nm of amorphous silicon. A further alternative embodiment could be simply to deposit about 40-60 nm or about 50 nm of amorphous on poly silicon on glass substrate without any other layers or coatings.

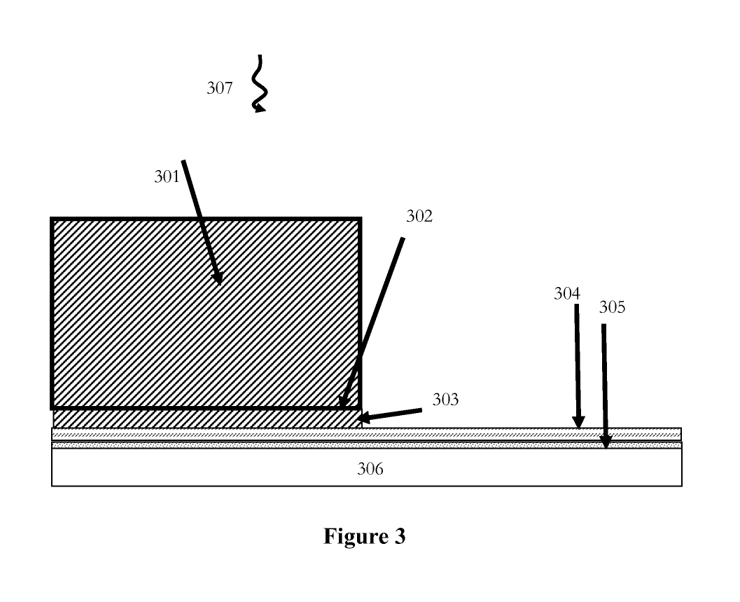

FIG. 3 illustrates an exemplary structure including a silicon-containing piece and a substrate, showing laser irradiation from the top, consistent with aspects related to the innovations herein. The system of FIG. 3 is similar to that of FIGS. 1 and 2, including the substrate 306, layers 305, and 304, silicon-containing material 301, 303, and laser 307. The implementation shown in FIG. 3 illustrates the laser 307 being applied from the top, through the silicon-containing material 301/303.

Referring to FIG. 3, this alternative implementation where the laser anneal is performed through the silicon wafer instead of through the substrate is shown. Here, the glass 306 may again be again coated with a layer 305 and another layer 304 may be deposited on top of layer 305. This may be followed by bonding the silicon wafer/piece 301 on the layer 304 using the laser anneal. The silicon wafer wafer/piece 301 may already be implanted with ions at a desired depth creating the damage layer 302. A sub-piece 303 will remain attached to the glass and the layers deposited on top of the glass after the cleaving process. In these implementations, the laser 307 is used on the silicon wafer from the top. According to some implementations, the wavelength is chosen to heat up the silicon wafer sufficiently to cause stress at the damaged layer 302. In some implementations, the laser wavelength can be between about 0.7 μm and about 1.1 μm. In one exemplary implementation, an DPSS laser (diode-pumped solid state) laser is used with a wavelength of 1.06 μm. The laser spot size can be between about 5 μm and about 200 μm or can be a line source with the width in the range of about 5 to about 200 μm. In one exemplary implementation, a spot size of around 50 microns may be used for the laser. This spot is then rastered on the piece 301, so that it covers the entire wafer within a few minutes. In another exemplary implementation, the optics are configured to give a line source of the laser which is about several millimeters long and about 50 microns wide. In a third exemplary implementation, two lasers may be used. One is from the top and second is from the bottom through the glass substrate.

Before turning to some illustrative processes, it should be noted that aspects of the innovations herein consistent with these aspects enable use of less costly substrate materials, such as substrates having atomically rougher surfaces (e.g., >5 A rms roughness, etc.). Here, for example, such features may avoid severe limitations of existing techniques on the use of standard quality glass substrates which typically have rougher surfaces. This enables separation of silicon layers reliably and/or at low enough cost, as compared, e.g., to existing systems and commercial manufacture of silicon on insulator that rely on thermal treatments alone.

As set forth in more detail elsewhere, aspects of the innovations herein may include one or more of the following and some variations of substrates and laser position are also described herein: use of laser scanned across the silicon wafer in contact with various layers deposited on glass to help the bonding and cleaving of silicon on glass to desired thickness; use of laser anneal to strengthen the bond between the silicon and the underlying layers and/or substrate; use of laser anneal to weaken the damaged layer created by the light ion implantation; and/or application of laser(s) either through the glass or through the silicon layer or both.

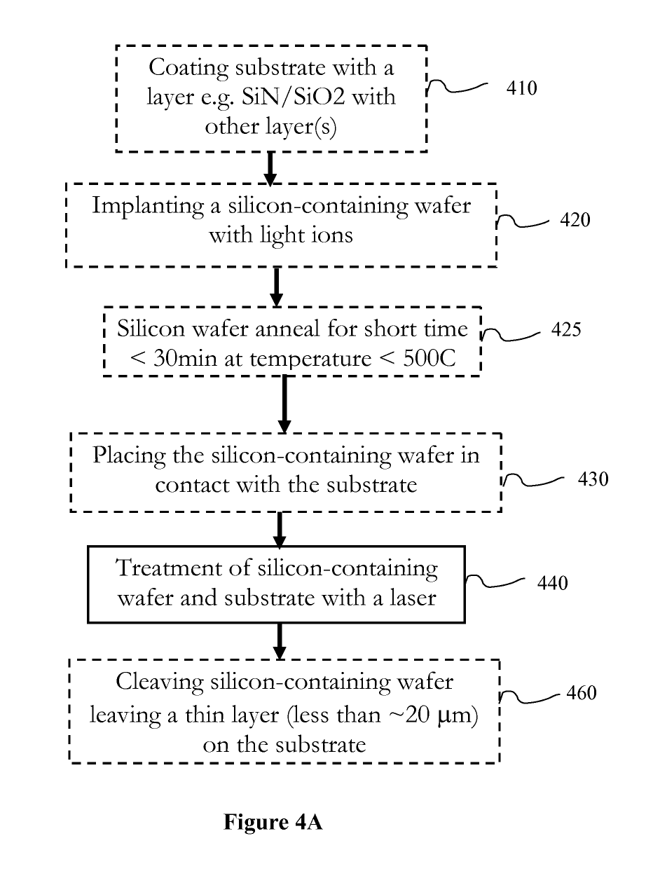

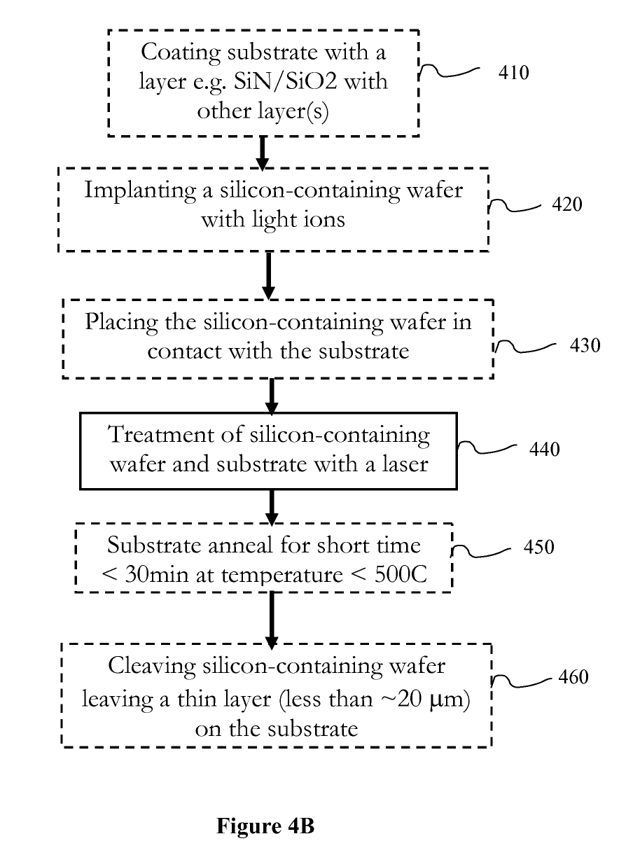

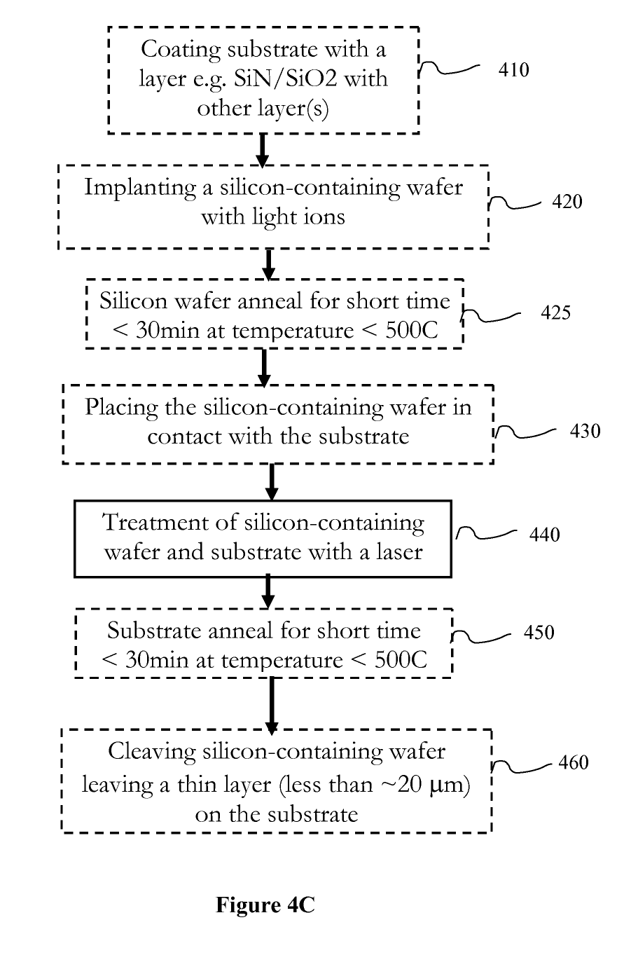

FIG. 4A illustrates an exemplary method of producing a composite substrate consistent with aspects of the innovations herein. As shown in FIG. 4, an optional step of coating the substrate with a layer 410, e.g. SiN/SiO2, SiN/SiO2 and additional layers, SiN/SiO2/amorphous silicon, or other layers such as anti-reflective layers, etc., may initially be performed. In general, however, a step of implanting the silicon-containing material with light ions 420 is first performed, i.e., to a specified depth at which the material is to be cleaved. In certain implementations, where the cleaving of the material is not desired, the implantation step can be skipped and entire thickness of the silicon-containing material may be left on the substrate without cleaving after the laser irradiation/treatment. After this, a short anneal 425 may optionally be performed on the silicon wafer may be done with a time of less than 30 min and a temperature less than 500 C. Next, the silicon-containing material is brought into contact with the substrate 430. Then, a step of treating/irradiating the silicon-containing material and the substrate with a laser 430 is performed, consistent with the innovations set forth elsewhere herein.

Further, in some optional, exemplary implementations, e.g. as shown in FIGS. 4B and 4C, an overall substrate anneal step 450 (e.g., furnace anneal, rapid thermal anneal [RTA], etc.) of shorter duration may then be performed, such as less than 30 minutes, and within certain temperature ranges, such as below about 500° C. And, in further optional and exemplary implementations, a final step of cleaving the silicon-containing material may be performed 460, e.g., to leave a thin layer of the silicon-containing material on the substrate. Here, for example, layers of less than about 20 microns may be left on the substrate, such as layers in the range of about 0.1 to about 12 microns, or about 0.25 to about 1 micron, or about 0.5 micron. In FIG. 4C, both the optional anneals i.e. 425 on the silicon wafer and 450 which is the overall substrate anneal are shown.

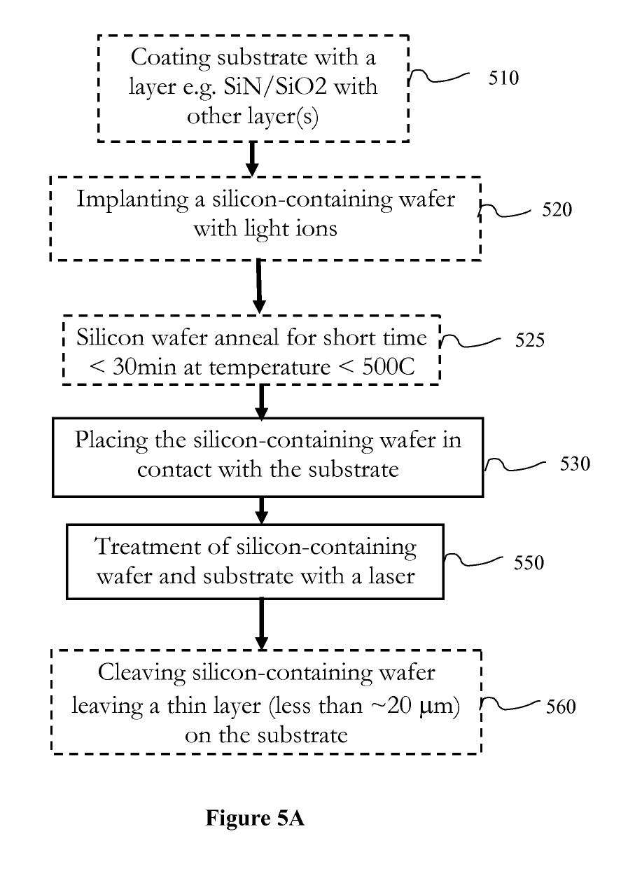

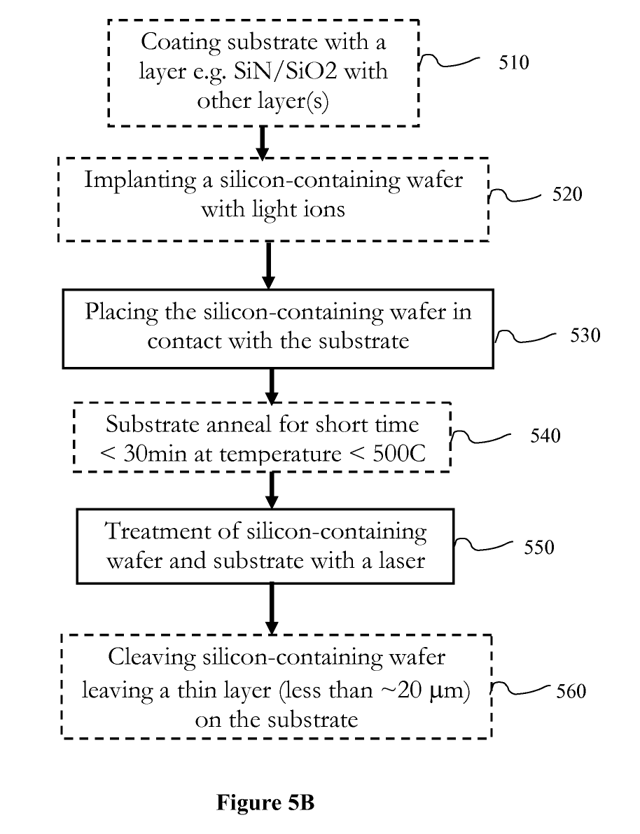

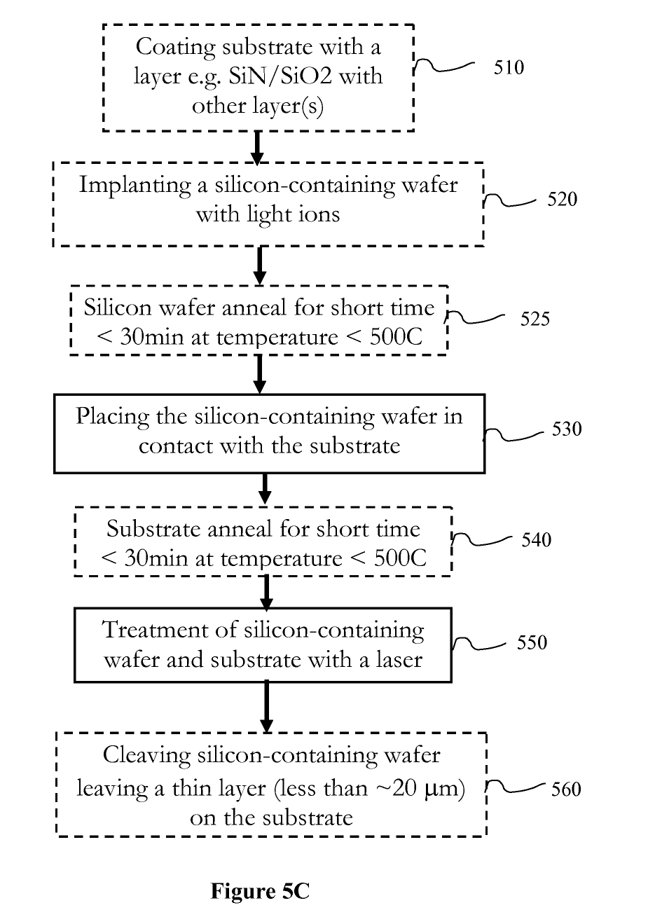

FIGS. 5A, 5B and 5C illustrate further exemplary methods of producing a structure, consistent with aspects related to the innovations herein. The implementation of FIGS. 5A, 5B and 5C may be similar to that of FIGS. 4A, 4B and 4C, including steps of coating 510, implanting 520, placing the material into contact with the substrate 530, annealing 540, laser treatment/irradiation 550, and cleaving 560. However, in the implementation illustrated in FIGS. 5B and 5C, the substrate anneal (e.g., furnace, RTA, etc.) is performed prior to the laser irradiation. The substrate anneal heats the entire substrate up to the specified temperature in contrast to a laser irradiation, which only heats up the silicon-containing material and the layer(s) 510, while leaving the substrate without a significant temperature rise. In FIG. 5A, an optional short anneal step 525 may be performed on the silicon wafer. Here, for example, such anneal may be performed over a time duration of less than 30 min and a temperature at a temperature or in a range less than 500 C. In FIG. 5C, both the optional anneals i.e. 525 on the silicon wafer and 540 which is the overall substrate anneal may be performed. The laser chosen for treatment in exemplary implementations may have a wavelength between about 350 nm and about 1070 nm, such as wavelengths between 350 nm and 700 nm, or about 515 nm or about 532 nm. The cleaving of the silicon-containing wafer is done at about the range (Rp) of the light ion implantation. However, due to the statistical nature (straggle) of the implantation, this cleave plane is not perfectly precise and leads to a somewhat rough surface after cleaving.

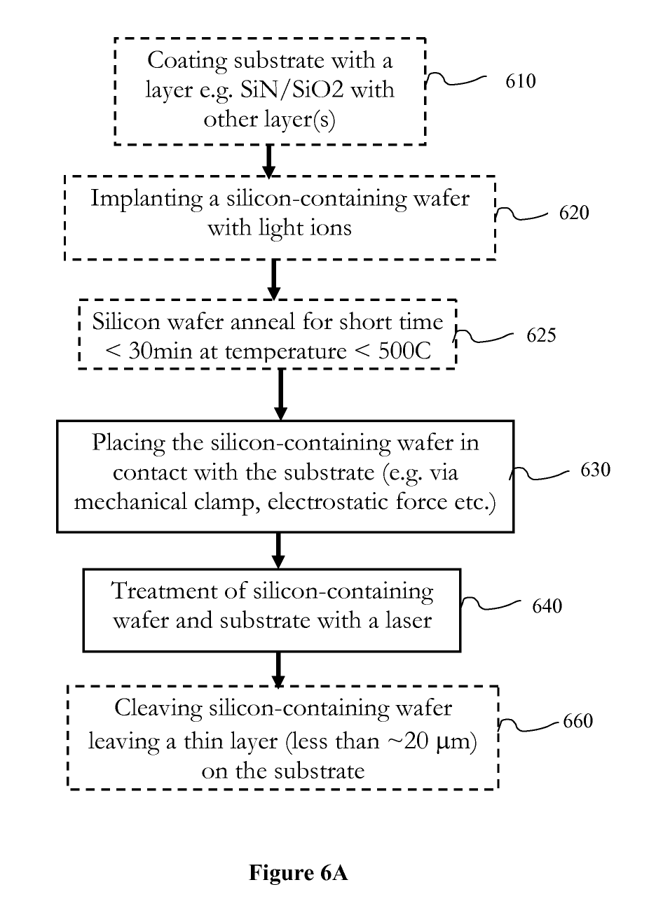

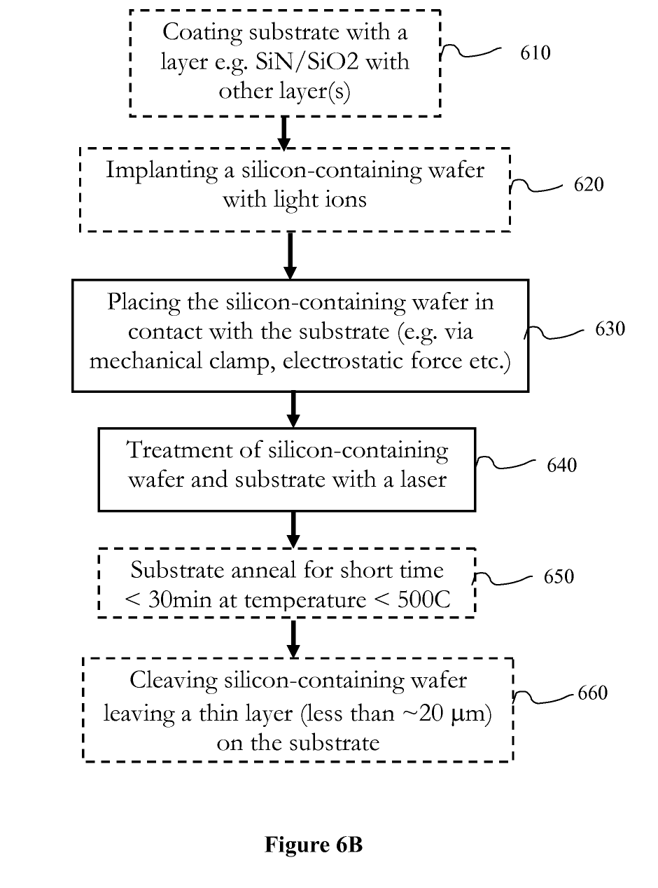

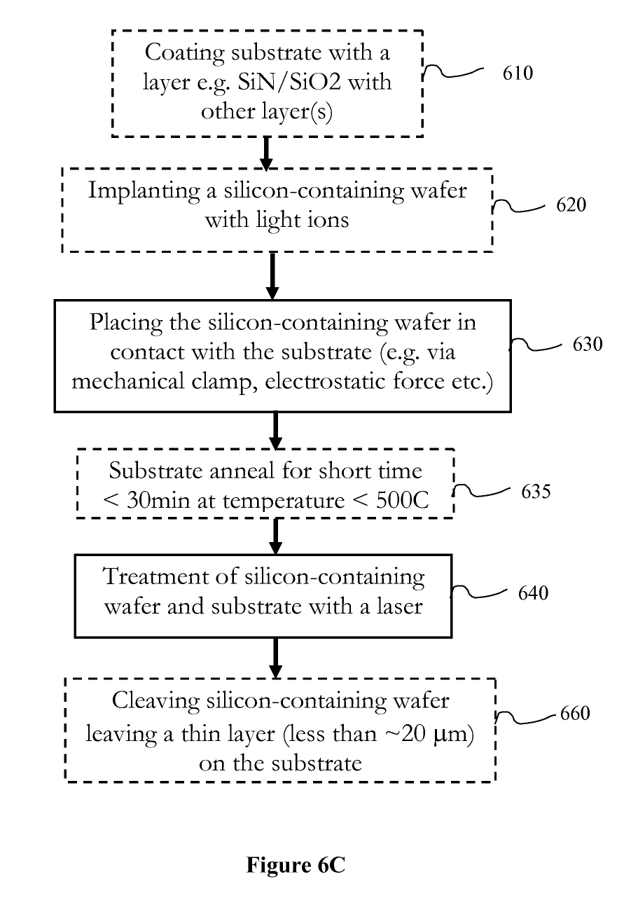

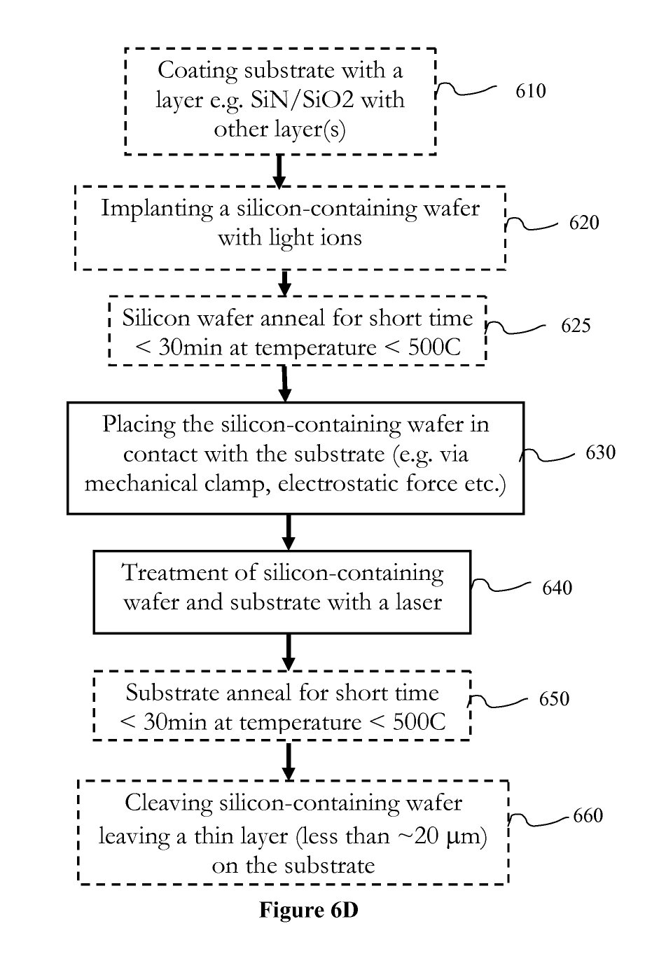

FIGS. 6A, 6B, 6C and 6D illustrate still other exemplary methods of producing structures, consistent with aspects related to the innovations herein. The implementation of FIGS. 6A, 6B and 6D may be similar to that of FIGS. 4A, 4B and 4C, including steps of coating 610, implanting 620, placing the material into contact with the substrate 630, laser treatment/irradiation 640, annealing 650 and cleaving 660. In FIG. 6A, the optional short anneal step 625 on the silicon wafer is also shown. In FIG. 6C, the optional anneal step 635 is shown before the laser treatment/irradiaton. FIG. 6D illustrates performance of both the optional anneal steps 625 and 650. In the implementation illustrated in FIGS. 6A, 6B and 6C, the silicon-containing layer or wafer is placed in contact with the substrate using mechanical clamps, vacuum or electrostatic forces. In some implementations, pressure may applied to the silicon-containing layer to achieve good contact between the layer and the substrate. In exemplary implementations, the substrate may be glass such as borosilicate/borofloat glass or soda-lime glass. In other implementations, the substrate may be metallic such as steel or aluminum sheets or foils.

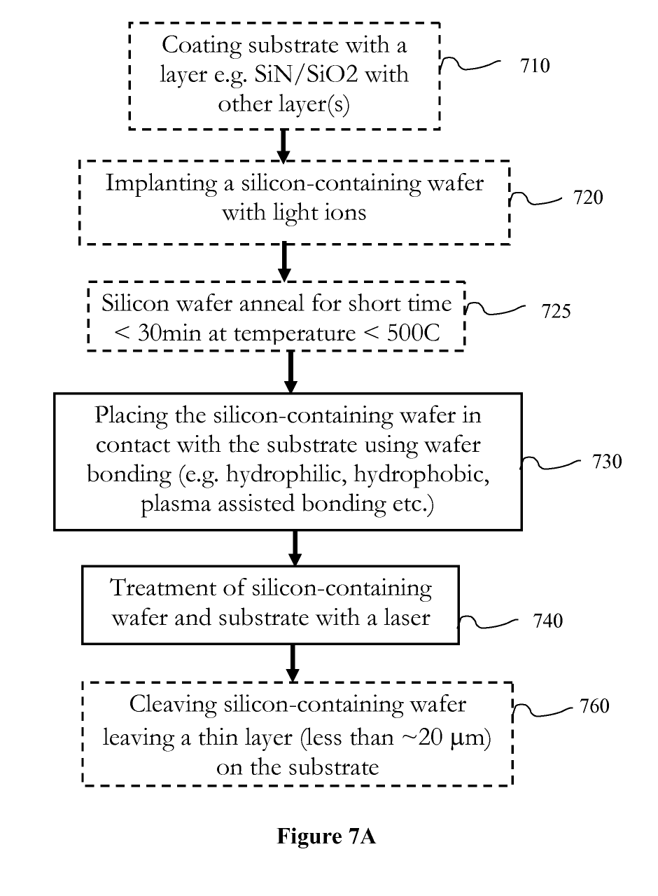

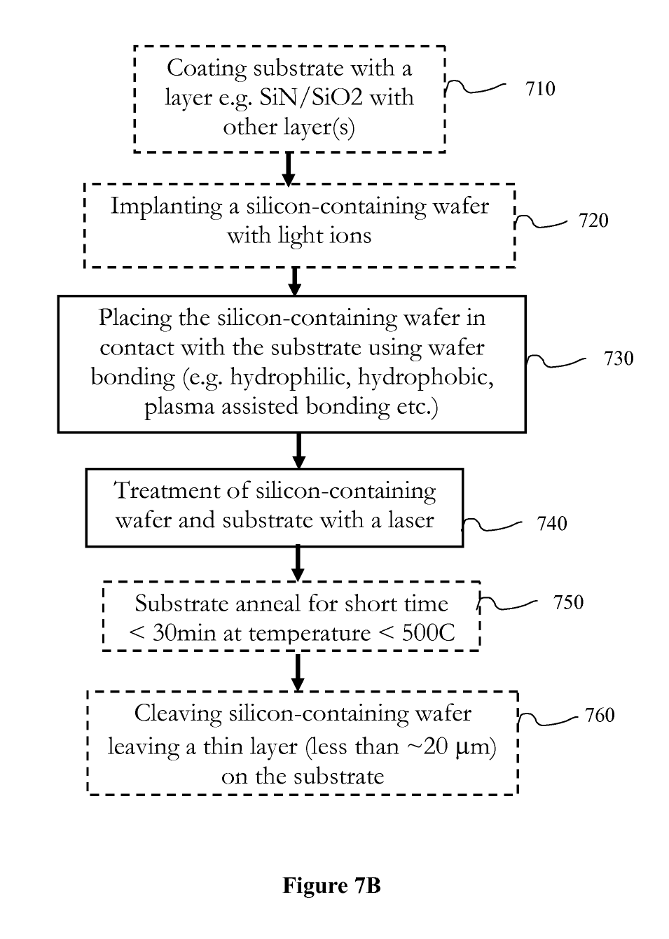

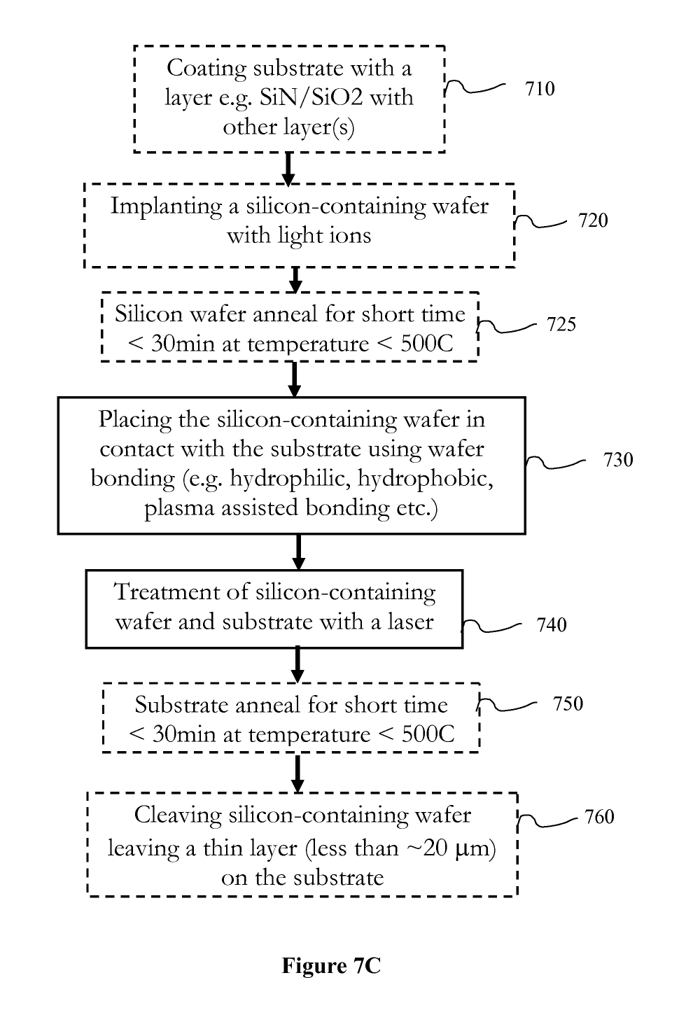

FIGS. 7A, 7B and 7C illustrate another exemplary method of producing a structure, consistent with aspects related to the innovations herein. The implementation of FIGS. 7A, 7B and 7C may be similar to that of FIGS. 4A, 4B and 4C, including steps of coating 710, implanting 720, placing the material into contact with the substrate 730, laser treatment/irradiation 740, annealing 750 and cleaving 760. The optional anneal step 725 for the silicon wafer is also shown FIG. 7A, similar to the one shown in FIG. 4A. In the implementation illustrated in FIGS. 7A, 7B and 7C, the silicon-containing layer or wafer may be placed in contact with the substrate using wafer bonding such as hydrophilic, hydrophobic or plasma assisted bonding. In these implementations as well, the substrate anneal (furnace or RTA) may be performed before or after the laser irradiation/treatment.

In alternative implementations of the innovation herein, further low temperature anneals may be performed before or after the laser anneal to assist with the cleaving process. In some implementations, such anneal can be between about 200° C. to about 500° C., in ranges of time spanning from 5 minutes to about 30 minutes. In one exemplary implementation, an anneal is done at 300° C. for 15 minutes prior to the laser treatment. In another exemplary implementation, the silicon wafer can be annealed after implantation at 250° C. for 10 min after the implantation step.

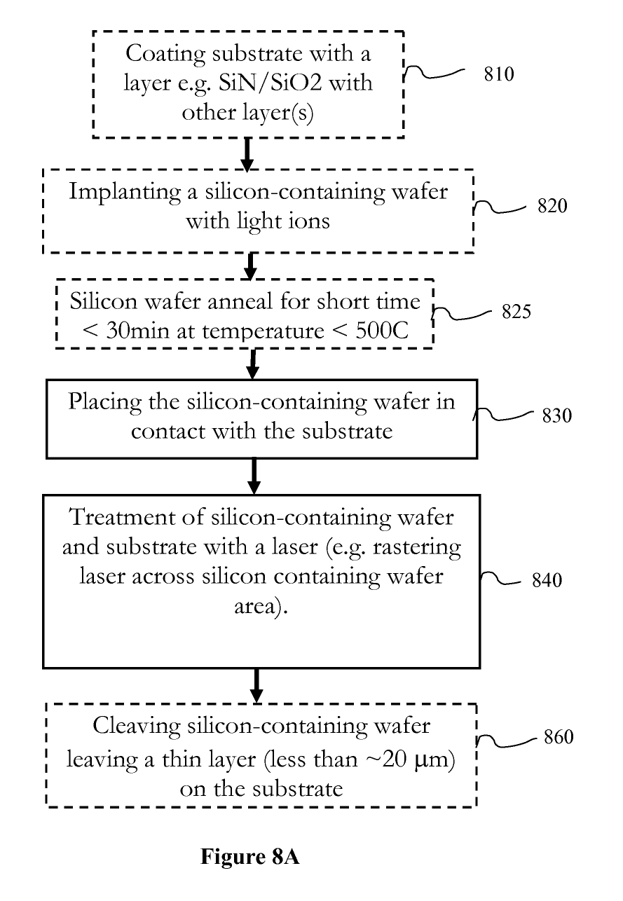

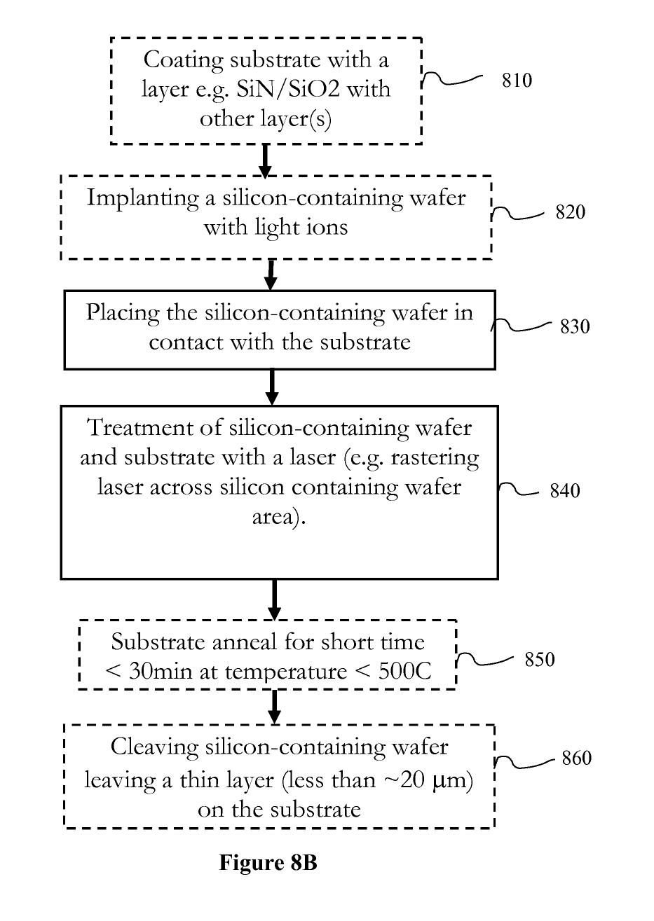

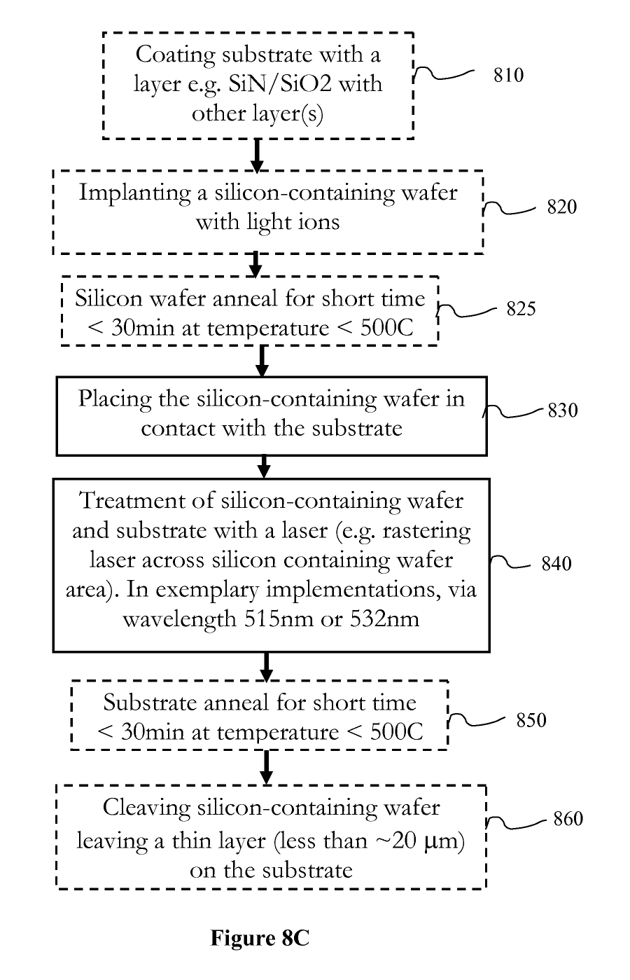

FIGS. 8A, 8B and 8C illustrate still other exemplary methods of producing a structure, consistent with aspects related to the innovations herein. The implementations of FIGS. 8A, 8B and 8C may be similar to that of FIGS. 7A, 7B and 7C, including steps of coating 810, implanting 820, silicon wafer anneal 825, placing the material into contact with the substrate 830, laser treatment/irradiation 840, annealing 850 and cleaving 860. According to the implementations illustrated in FIGS. 8A, 8B and 8C, the step of laser irradiation may include treatment (e.g., rastering, line source, etc.) of the silicon-containing material and substrate with a laser having a wavelength of 515 nm or with a laser having a wavelength of 532 nm, which, by virtue of the specific applications and parameters set forth herein, impart distinctive improvements in weakening the damaged layer created by the light ion implantation (yielding beneficial cleaving characteristics) while also strengthening the bond between the silicon-containing material and the substrate.

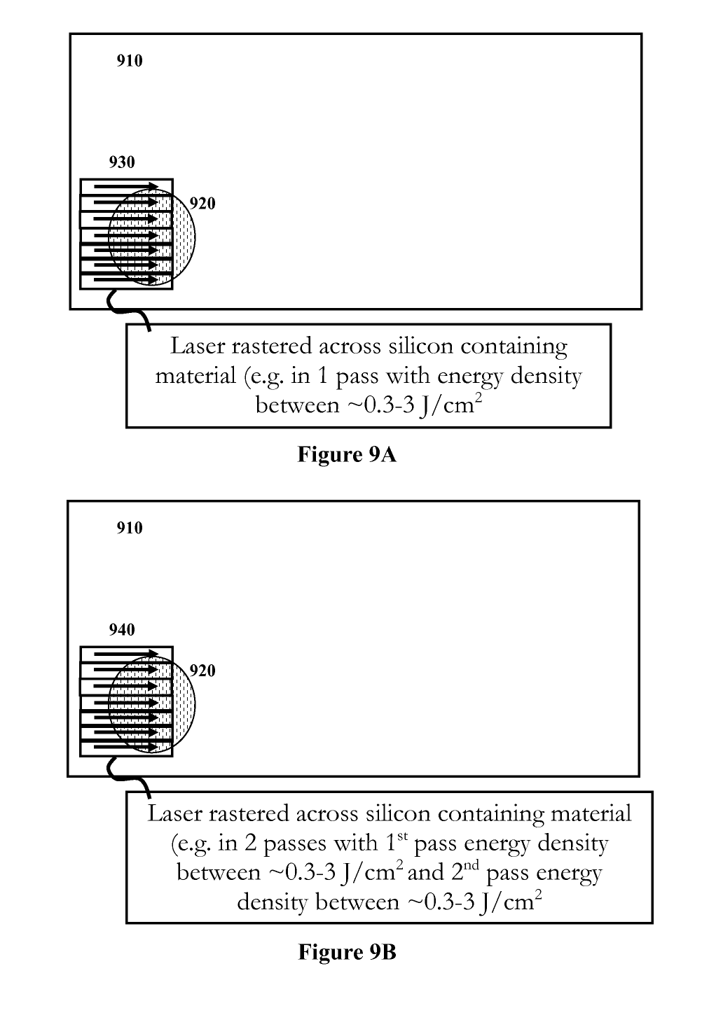

FIGS. 9A-9B illustrate still further exemplary aspects of producing a structure, including laser treatment, consistent with aspects related to the innovations herein. Referring to FIG. 9A, an exemplary laser irradiation/treatment process is shown, comprised of a single pass of the laser over each region at an energy density of between about 0.3 and about 3 J/cm2. The energy density is calculated by dividing the laser pulse energy by the area of the spot. This depends on laser power, laser repetition rate, scan speed and the focusing optics used. Indeed, the laser may be focused as a line source rather than as a spot. However, the energy density calculations are similar i.e., dividing the laser pulse energy by the area of the line in case of a line source. In exemplary implementations, there may be significant overlap of neighboring spots/lines as the laser is rastered across the silicon-containing material. In some implementations, the laser rastering may start on the substrate outside the area of the silicon-containing material and then move on to the silicon-containing material. In other implementations, the rastering may not cover the complete area of the silicon-containing material. In addition, multiple passes of the laser may also be performed. For example, as shown in FIG. 9B, an exemplary rastering process including 2 passes of the subject laser is shown. FIG. 9B illustrates an exemplary implementation wherein the laser irradiation/treatment comprises a first pass of the laser at an energy density of between about 0.3 and about 3 J/cm2, and a second pass of the laser at an energy density of between about 0.3 and about 3 J/cm2. Further, in such implementations, the laser may be passed over each region at an energy density of about 2 J/cm², e.g., for lasers of 515 nm or 532 nm, and especially for absorptions depths of less than a micron. Additionally, in multi-pass implementations, energy density may also be increased or decreased as between the differing passes. Indeed, results of improved bonding or better cleaving have been unexpectedly achieved as a function of varying the energy densities in this manner. Furthermore, other parameters of the laser application may also be varied, such as the speed at which the laser is passed of the structure. For example, the laser may be passed over the substrate at slower speeds, such as between about 0.0001 to about 0.01 cm²/sec, and/or at higher speeds, such as between about 0.01 to about 10 cm²/sec. In one exemplary implementation, here, a step of laser irradiation/treatment may comprise a first pass of the laser, at a speed/rate of about 0.0001 to about 0.01 cm²/sec, at an energy density of between about 0.3 and about 1 J/cm2, and a second pass of the laser, at a speed/rate of about 0.01 to about 10 cm²/sec at an energy of between about 1 and about 3 J/cm2.

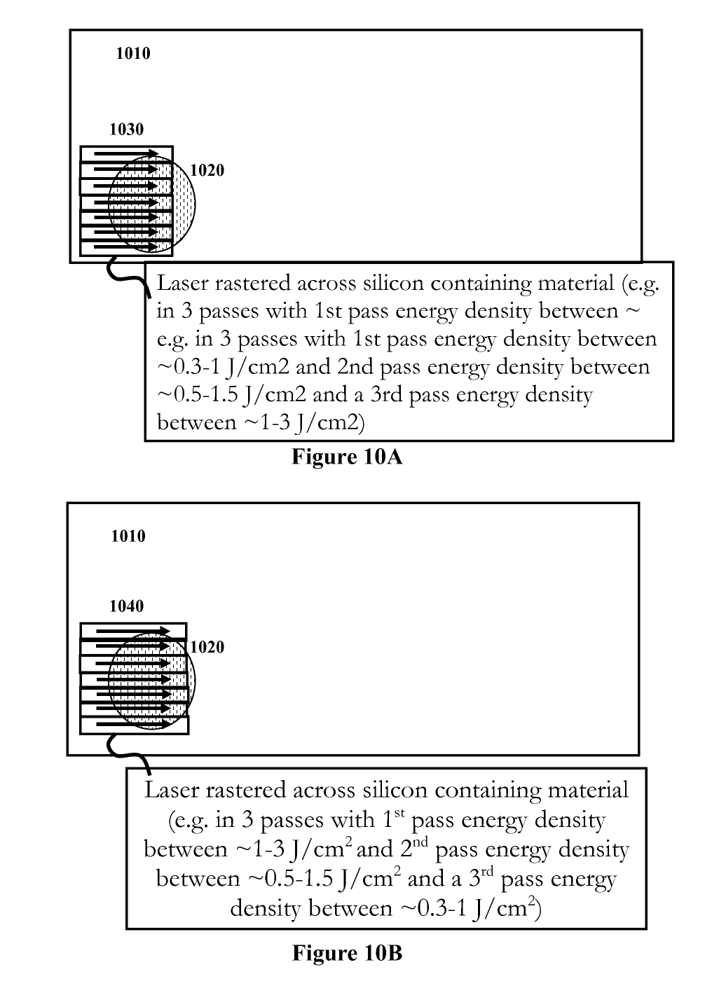

FIGS. 10A-10B illustrate exemplary innovations regarding laser treatment of the silicon-containing material including 3 passes of a laser, consistent with aspects related to the innovations herein. Referring to FIGS. 10A-10B, exemplary laser irradiation/treatment processes are shown, comprised of 3 passes of a laser or different lasers over each region at an energy density of between about 0.3 and about 3 J/cm2. For example, FIG. 10A illustrates an exemplary implementation wherein the laser irradiation/treatment comprises a first pass of the laser at an energy density of between about 0.3 and about 1 J/cm2, a second pass of the laser at an energy density of between about 0.5 and about 1.5 J/cm2, an a third pass of the laser at an energy density of between about 1 and about 3 J/cm2. Further, FIG. 10B illustrates another exemplary implementation wherein the laser irradiation/treatment comprises a first pass of the laser at an energy density of between about 1 and about 3 J/cm2, a second pass of the laser at an energy density of between about 0.5 and about 1.5 J/cm², an a third pass of the laser at an energy density of between about 0.3 and about 1 J/cm².

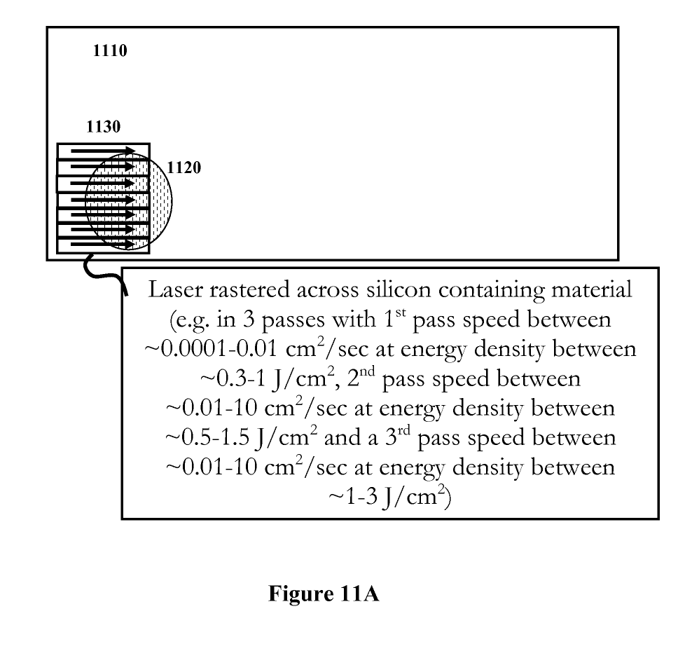

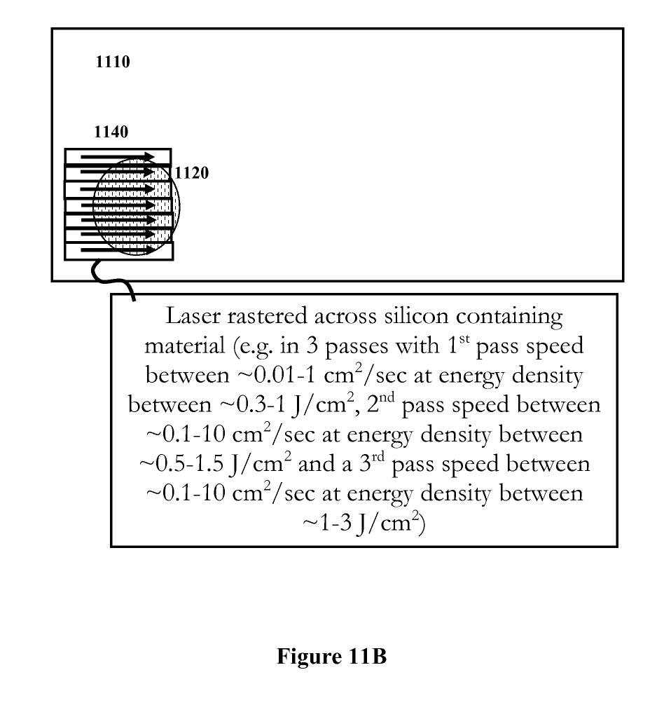

FIGS. 11A-11B illustrate further exemplary innovations regarding laser treatment of the silicon-containing material, consistent with aspects related to the innovations herein. Referring to FIGS. 11A-11B, exemplary laser irradiation/treatment processes are shown, comprised of 3 passes of a laser or different lasers over each region at different speeds and/or energy densities. For example, FIG. 11A illustrates an exemplary implementation wherein the laser irradiation/treatment comprises a first pass of the laser, at a speed/rate of about 0.0001 to about 0.01 cm²/sec, at an energy density of between about 0.3 and about 1 J/cm2, a second pass of the laser, at a speed/rate of about 0.01 to about 10 cm²/sec at an energy of between about 0.5 and about 1.5 J/cm2, and a third pass of the laser, at a speed/rate of about 0.01 to about 10 cm²/sec at an energy of between about 1 and about 3 J/cm2. Further, FIG. 11B illustrates another exemplary implementation, wherein the laser irradiation/treatment comprises a first pass of the laser, at a speed/rate of about 0.01 to about 1 cm2/sec at an energy density of about 0.3 to about 1 J/cm², second pass of a laser at a speed/rate of about 0.1 to about 10 cm2/sec at an energy density of about 0.5 to about 1.5 J/cm², and a third pass of a laser at a speed/rate of about 0.1 to about 10 cm2/sec at an energy density of about 1 to about 3 J/cm².

In accordance with innovations herein, then, temporal requirements for the bonding and cleaving of the silicon wafer on glass may be reduced from 3-4 hours at 550° C. to less than 45 minutes. This may reduce the cycle time of the process as well as the cost. As such, systems and methods herein may be used to realize lower cost semiconductors and solar cells. Innovative systems and methods may also be applied to save cost and cycle time in preparing silicon-on-glass substrates for the production of flat panel displays.

As such, especially in the case of solar cell fabrication, the methods herein may readily enables a continuous production line, as most other steps are less than 10 minutes long. Accordingly, features imparting such improved processing times are especially innovative as drawbacks of having time-consuming processing steps (4 hours, etc.) include the need for large amounts of inventory and storage, especially before and after lengthy anneal steps. These drawbacks significantly increase the cost and complexity of a solar cell manufacturing line. Moreover, various implementations of the innovations herein entail only about 15 minutes and hence perfectly integrate with continuous, low-cost solar cell production lines.

Turning to some specific applications, namely solar cell applications, use of the innovations herein with a SiGe (silicon-germanium) wafer, piece or layer, rather than pure silicon material, increases the light absorption in the infrared region, thereby increasing the efficiency of solar cells. In one exemplary implementation, a silicon-germanium layer is used for the solar cell. For certain implementations, the ratio of silicon to germanium may be more than 80%. In other implementations, the ratio of silicon to germanium may be 90%/10%, respectively. In still further implementations, the germanium may comprise only between about 2% and about 5%. Here, a silicon-germanium layer on top of a substrate such as glass may be crystallized as described above.

In still further exemplary implementations of the systems, methods and products herein, silicon wafer bonding and cleaving innovations are used with other substrates such as plastic or stainless steel instead of silicon/glass. The use of plastic substrates along with these innovations enables low cost flexible solar cells which can be integrated more easily with, e.g., buildings. One exemplary use of plastic substrates with the innovations herein includes integrating solar cells with windows of commercial buildings (also known as BIPV or Building-integrated-photovoltaics).

Further, aspects of the innovations herein may include coating layers either on the outside of the glass layer, or in between the glass and the silicon layer to be cleaved, or both sides. According to the certain innovations, for example, the silicon-based layer may also be other semiconductor materials such as SiGe (silicon-germanium) or SiC (silicon-carbide). For solar cell applications in particular, use of the innovations herein with SiGe (silicon-germanium) increases the light absorption in the infrared region and thus increases the efficiency of solar cells. In one exemplary implementation, a silicon-germanium layer with the silicon-germanium ratios listed above (>80%/<20% or ˜90%/˜10%), or of about 2 to about 5% germanium may be used for the solar cell. The silicon-germanium layer on top of the glass substrate may be bonded with the silicon wafer as described above.

Aspects of the innovations herein may also include one or more of the features, functionality and/or processing steps set forth in related application Ser. No. 12/954,837, filed Nov. 26, 2010, published as US2011/______A1, now U.S. Pat. No. ______, incorporated herein by reference in entirety.

As set forth herein, various methods of producing composite solar cell structures composed of a silicon-containing material bonded to a substrate are disclosed. According to some illustrative implementations, exemplary methods may comprise engaging the silicon-containing piece into contact with a surface of the substrate, wherein the substrate includes one or more SiN/SiO2/Si-containing layer(s)/coating(s) on the surface, and irradiating/treating the silicon-containing piece with a laser having a wavelength of between about 350 nm to about 1070 nm, such that complete bonding between the piece and the glass substrate is achieved without need for further anneal. Further, the methods may include any of the other features set forth herein. Additionally, the innovations herein may of course be part of other processes associated with fabrication of the subject elements (e.g., solar panels, thin film solar cells, flat panel displays, etc.), such as set forth in U.S. patent application Ser. No. 12/845,691, filed Jul. 28, 2010, published as US2011/0101364A1, now U.S. Pat. No. ______, incorporated herein by reference in entirety, i.e., the features shown in FIGS. 1-16 and the associated written description thereof.

As such, in accordance with innovations herein, temporal requirements for the bonding and cleaving of the silicon wafer on glass may be reduced from 3-4 hours at 550° C. to less than 45 minutes. This may reduce the cycle time of the process as well as the cost. As such, systems and methods herein may be used to realize lower cost semiconductors and solar cells. Innovative systems and methods may also be applied to save cost and cycle time in preparing silicon-on-glass substrates for the production of flat panel displays.

### Flat Panel Display

### Other Embodiments

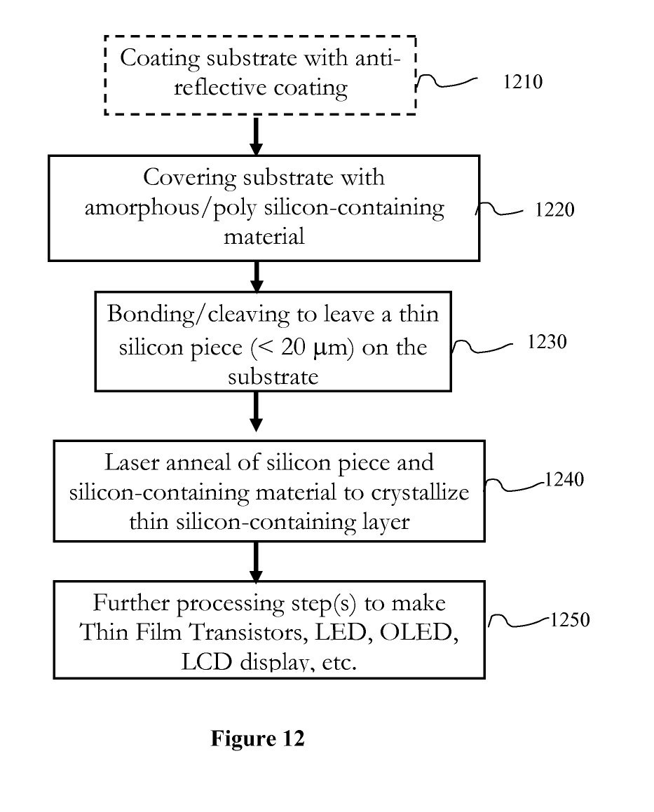

FIG. 12 illustrates yet another exemplary method including crystallization of silicon/silicon-based materials on a substrate, consistent with aspects of the innovations herein. Referring to FIG. 12, an exemplary process including one or more steps related to fabrication of flat panel (LED, OLED, LCD, etc.) displays and/or thin film transistors is disclosed. FIG. 12 illustrates an initial series of steps, steps 1210 and 1220. Specifically, initial steps of placing the SiN/SiO2/Si-containing layer or layers, such as a SiN, SiO2, SiON etc. layers and/or amorphous/poly Si layer(s), on the substrate 1210 and 1220 (in any order) are shown. Bonding and cleaving a silicon wafer or piece consistent with the innovations described herein is shown as step 1230. Heating the seed layer/amorphous-poly material 1240 into crystalline or partially crystalline form may be performed, such as via use of a laser. Next, in 1250, one or more further processing steps related to making thin film transistors and/or flat panel (LED, OLED, LCD, etc.) displays may be performed.

Here, in such flat panel display embodiments, the SiN/SiO2/Si-containing coating(s)/layer(s) may be comprised of one or more of the materials set forth above. Further, another illustrative flat panel display fabrication process may involve a single layer/coating comprising Si (amorphous silicon or poly silicon) in thickness ranges of between about 1 nm and about 100 nm, between about 20 nm and about 75 nm, or between about 40 nm and about 50 nm, or of about 45 nm. Here, for example, such layer may be deposited by PECVD using SiH4. In these flat panel display and thin film transistor embodiments, the substrate may be comprised of materials used to fabricate the subject device, such as e.g. aluminosilicate glass.

Other aspects of the innovations herein will be apparent to those skilled in the art from consideration of the specification and practice of the innovations herein. It is intended that the specification and examples be considered as exemplary only, with a true scope and spirit of the inventions being defined by the scope of the claims as per the totality of the disclosure in combination with the relevant knowledge of an ordinary artisan.

1. A method of producing a composite structure composed of a silicon-containing material bonded to a substrate, the method comprising:
implanting ions into silicon-containing material to a depth;
providing a SiN/SiO2/Si-containing layer/coating on the substrate;
engaging the silicon-containing piece into contact with the substrate; and
irradiating/treating the silicon-containing piece with a laser having a wavelength of between about 350 nm to about 1070 nm.

2. The method of claim 1 further comprising providing a plurality of SiN/SiO2/Si-containing layers/coatings on the substrate.

3. The method of claim 2 wherein the plurality of layers/coatings includes a first layer/coating comprising SiN.

4. (canceled)

5. The method of claim 1 wherein the substrate is a borosilicate/borofloat glass or a soda-lime glass.

6-16. (canceled)

17. The method of claim 1 further comprising cleaving the silicon-containing material along a surface established at about the depth at which the ions are implanted.

18-19. (canceled)

20. The method of claim 1 wherein the substrate includes a base portion composed of glass, plastic or metal.

21. (canceled)

22. The method of claim 1 further comprising of a step of annealing the composite structure.

23-32. (canceled)

33. The method of claim 1 wherein the silicon-containing piece is of a thickness of less than about 100 microns such that, after completion of the laser irradiation step, the structure is thicker (bulges) at a region where the silicon-containing piece was originally placed.

34. (canceled)

35. A method of producing a composite structure composed of a silicon-containing material bonded to a substrate, the method comprising:
implanting ions into silicon-containing material to a depth;
holding the silicon-containing piece into contact with a surface of the substrate, wherein the substrate includes a SiN/SiO2/Si-containing layer/coating on the surface;
irradiating/treating the silicon-containing piece with a laser having a wavelength of between about 350 nm to about 1070 nm; and
cleaving the silicon-containing material along a surface established at about the depth at which the ions are implanted.

36. The method of claim 35 wherein the substrate includes a plurality of SiN/SiO2/Si-containing layers/coatings provided on the surface prior to engaging the piece.

37. The method of claim 35 wherein the plurality of layers/coatings includes a first layer/coating comprising SiN.

38-48. (canceled)

49. The method of claim 51 wherein the substrate comprises aluminosilicate glass.

50. (canceled)

51. The method of claim 82 wherein the layer/coating comprises amorphous silicon or poly silicon.

52-55. (canceled)

56. The method of claim 1 wherein the step of irradiation comprises:
a first pass of the laser at an energy density of between about 0.3 and about 3 J/cm2.

57. (canceled)

58. The method of claim 82 wherein the step of irradiation comprises:
a first pass of the laser at an energy density of between about 0.3 and about 1 J/cm2;
a second pass of the laser at an energy density of between about 0.5 and about 1.5 J/cm2; and
a third pass of the laser at an energy density of between about 1 and about 3 J/cm2.

59. (canceled)

60. The method of claim 82 wherein the step of irradiation comprises:
a first pass of the laser, at a speed/rate of about 0.0001 to about 0.01 cm²/sec, at an energy density of between about 0.5 and about 1 J/cm2; and
a second pass of the laser, at a speed/rate of about 0.01 to about 10 cm²/sec at an energy of between about 1 and about 3 J/cm2.

61. The method of claim 51 wherein the step of irradiation comprises:
a first pass of the laser, at a speed/rate of about 0.0001 to about 0.01 cm²/sec, at an energy density of between about 0.5 and about 1 J/cm2;
a second pass of the laser, at a speed/rate of about 0.01 to about 10 cm²/sec at an energy of between about 1 and about 2 J/cm2; and
a third pass of the laser, at a speed/rate of about 0.01 to about 10 cm²/sec at an energy of between about 2 and about 3 J/cm2.

62-65. (canceled)

66. The method of claim 82 wherein the silicon-containing element is a layer, a piece or a wafer.

67-81. (canceled)

82. A method of producing a composite structure within a process of fabricating a flat panel display, the composite structure composed of a silicon-containing material bonded to a substrate, the method comprising:
engaging the silicon-containing material into contact with a surface of the substrate, wherein the silicon-containing material has ions implanted therein to a depth and the substrate has a SiN/SiO2/Si-containing layer/coating on the surface; and
irradiating/treating the silicon-containing piece with a laser having a wavelength of between about 350 nm to about 1070 nm.
